(19) United States
(12) Patent Application Publication
(10) Pub. No.: US 2005/0279403 A1
(43) Pub. Date: Dec. 22, 2005

(54) Architectural and landscape devices having solar lights

(76) Inventor: Steve Michael Kube, Charlotte, NC (US)

Correspondence Address: Steve M. Kube, 2233 East Providence Drive, Charlotte, NC, 28270, US

(21) Appl. No.: 10/869,784

(22) Filed: Jun. 16, 2004

(51) Int. Cl. H01L 31/00

(52) U.S. Cl. 136/291; 136/244; 136/251

(57) ABSTRACT

Solar powered lighting fixtures are combined with a variety of landscape and architectural accent objects, including windsocks, wind chimes, and other wind sensitive art objects. The combinations thus provide extended viewing of the objects as well as providing unique ways of illuminating and viewing the objects. The articles of manufacture provide new ways of marking and otherwise adorning and illuminating spaces with a variety of architectural and landscaping art objects and wind driven devices while also providing a way to immediately perceive the relative strength and direction of wind in an environment from a distance.

### FIELD OF THE INVENTION

The invention relates to solar powered landscape and architectural lighting used in combination with wind driven landscape and architectural accents such as windsocks, wind chimes, and or other substantially ornamental objects.

### BACKGROUND OF THE INVENTION

Solar landscape and architectural lighting has become quite popular. Solar light fixtures of this nature have been around for many years, are low cost, and available at many thousands of retail locations. Essentially these devices have a solar cell for collecting solar energy and converting it to electrical energy, which is stored in one or more rechargeable batteries, and an LED, or other suitable light source, that is lit after dark. They also have electronic circuitry to control the charging of the batteries and to switch the light on at night. Usually these devices are positioned close to the ground to illuminate a walkway or path, or to delineate or mark boundaries such as the edges of driveways, etc. One major advantage of these lights is that they need no wiring to install them. Being free of leads, we can do interesting things with them that can't as easily be done with wired lighting.

Until recently most of these solar light fixtures have used yellow LED's however; recently bright white LED's have been introduced into the fixtures. Also, fluorescent bulbs are now being driven by solar landscape lighting fixtures. With brighter light sources we can do more with these solar light fixtures. One example is to install the solar light fixture into the mouth of a decorative windsock and have the light illuminate the windsock at night. Another example is to suspend wind chimes under a hanging solar light fixture to illuminate the wind chimes at night. Also we can suspend other wind driven ornamental devices, or art objects, such as “wind devas”, under a hanging solar light fixture. “Wind Devas” can be seen at www.winddeva.com.

We can suspend a windsock with solar light fixture from a rigid or flexible flagpole for example, which positions the solar fixture away from a house, beyond the shadow of the eaves, where it can collect solar energy. Hanging windsocks from flagpoles like this is normal procedure. We intend to point out the need for positioning it in the sun when a solar light is included in the windsock. We can suspend the windsock however we want to, but we want to put it in bright sunlight, and where it can gather solar energy as well as blow freely in the wind. Suspending it from a flexible rod, such as a fiberglass rod, the windsock and solar light will be free to move more dynamically in a wind, bouncing and dancing as it were, in a breeze.

There are many examples of ‘windsocks’ suitable for these purposes. A search on the internet will provide many examples that can be adapted to be illuminated at night using a solar light fixture. Many of them are very dynamic, designed to spin in the wind, with streamers, etc. for added effect. One url to nice examples of windsocks and spinners follows:
http://www.aboveitallkites.com/merch/list.shtml?cat=windsocks
   For over 50 windsock variations see:
http://www.obflag.com/windsocks.html

Note that we are not speaking of strictly utilitarian windsocks as might be found at an airfield for example. We are speaking of utilitarian as well as decorative windsocks that encompass a very wide array of designs and effects. Note that we do bring in a utilitarian effect of illuminating the windsock at night, with a solar light, so it can be viewed readily from a distance, even though it is night and the surroundings are dark. The illuminated windsock also lights up a surrounding space to some degree. Additionally, illuminating the windsock from inside produces a novel form of lighting, wherein we introduce the pleasing display of the light swinging, swaying, spinning and otherwise moving in the breeze at night. Even when there is no breeze, the light produced can be quite pleasing. The utilitarian effect of being able to discern wind direction and relative strength of the wind is present, as is the utilitarian effect of providing a dynamic lighting fixture which is quite pleasing. The decorative aspects are provided by designs, colors, materials, etc.

The solar light fixture can be concealed inside the mouth of a windsock for example, or it can be prominently located ‘above’ or outside the windsock.

Solar light fixtures normally used for landscape or architectural lighting are built to last many years. However, the windsocks may wear and fade in relatively short order. Therefore we want to allow for easily replacing the windsock. Replacing the windsock on the solar lighting fixture allows us to introduce another new way of decorating a space, as with changing the display according to seasons, holidays, etc. The user can change the lighting effect by simply changing the windsock. For example; bright colors can be used in the summer, subdued earth tones in autumn, a ghostly shape and design can be used during Halloween, etc. There is no need to let the sock wear out to change it for various seasons, holidays, and other occasions.

Additionally, we can provide windsocks and other objects to be illuminated with the solar light fixture to show off team colors, mascots, logos, patriotic colors and themes, affection for particular animals, plants, etc.

While most windsocks are made of fabrics, we can utilize films such as colorful polyester film, and or multi-layer films to give various lighting effects for example. This could include holographic diffraction grating films, polarizing films, etc.

We can also provide molded plastic objects to be lit with the solar light fixture. Example; a lightweight plastic pumpkin or jack-o-lantern, or a plastic snowman could be fabricated to be used with these fixtures.

There are many methods of detachably connecting a windsock to a solar light fixture that can be worked out by anyone having ordinary skill in the arts. A simple groove around the periphery of the light fixture that the windsock would span, and a rubber band to tightly grip the sock to the fixture around that groove is one example. A velcro type attachment means is another. Similarly, snaps, buttons, hooks and eyes, clips, etc. can be used to detachably connect windsocks and other accent items to solar lighting fixtures. We could also sew into the windsock an elastic band for holding it to a fixture.

Another use for these solar light fixtures is to provide ‘fabric’ light shades to be used with them. The shade is simple decorative cloth that may or may not be on a rigid wire or wire-like frame. The solar light fixture fits inside or above the shade and the fixture with shade gets suspended. This is not unlike Japanese Lanterns, which are made of paper. We want cloth or other material more suited to outdoor spaces subject to exterior weather and other conditions. Additionally, we can provide a solar light fixture to which a user wraps a piece of suitable fabric around to act as a lampshade. A simple decorative ‘silk’ scarf can be utilized for this purpose.

Solar light fixtures with cloth shades can be suspended from above, as from the eaves of a house, or on a line hung across a distance for this purpose, or mounted on a stand for example. The stand can be short or tall, in the ground, or on a railing, the side of a building, etc. Ideally the cloth will be loose fitting and able to flutter or wave somewhat in a breeze. Fringe or streamers may help in this matter.

One item of note here is that ordinarily solar light fixtures are typically hard plastic and or metal items. They are very functional, but sometimes lack a romantic, or aesthetic appeal. The simple flickering of a candle is often much more appealing than the steady, purposeful glare of the solar light counterpart. Adding a cloth shade that is able to sway, swing, or otherwise move in a breeze, would give a more appealing light in many instances. It can add a warmth or a softer feel that hard plastic or metal cannot.

Fabric shades or lamps can also be changed according to seasons, holidays, etc. Flashy colors, subdued colors, or even hand-painted silks can be used. Applique techniques for decorating the fabric are also useful. Figurines can be used here as well, such as ghostly figures for Halloween decorations. Snowmen for winter decor. Heart shaped shades for Valentines. Shamrocks for St. Patrick's Day, etc . . .

Combining Solar Light Fixtures with Wind Chimes;

Wind chimes are very popular landscape decorations, and or architectural accent items. These can benefit from adding a solar light fixture so they can be seen at night. Particularly those made with glass, crystal, and other translucent, or see through materials are striking when lit at night. The light shining directly on them can be quite pleasing. Cut glass and crystal can refract and reflect interesting patterns, such as rainbows. Colored glass is also very interesting in these direct lighting situations. Simple translucent colored beads can be arranged in pleasing ways to be illuminated by these lights. Again, a search on the internet for glass wind chimes will show many examples of these objects that can be combined with a solar light fixture to great appealing effect.

Adding a fabric lampshade to a solar light fixture with wind chimes provides a dynamic light and though the fabric may conceal the wind chimes to some degree, the sounds made are not obstructed and the light inside the lampshade can be more dynamic when shadows and reflections from the wind chimes are scattered onto the cloth.

Some very nice examples of wind chimes that would be nicely illuminated with solar lights can be seen at the following url:
http://www.anjian.com.au/productpages/windchimes/windchimes2.html

With these “Light & Wind Chime” fixtures in particular, and with solar lights and windsocks as well, we can introduce other color LEDs. Bright white will work just fine, but also interesting will be blue, green, red, yellow, etc. Super-bright varieties having water-clear lenses are most attractive. However, we can simply use white light sources and alter the coloration with the colors of the fabrics used with them.

Additionally, we can provide solar powered light fixtures having sparkling dangling items that move in the breeze. Like wind chimes, but without the sounds, these items hanging from threads or other suspension means, below the solar light, will refract, reflect, and scatter the light hitting them. Again, glass, crystal and other see through materials will work best. Some objects made of translucent plastics will work very nicely.

We can also use opaque objects that will cast shadows on lampshades when moving in a breeze. Similarly, reflective objects can be used to cast flecks of light around the interior of the lampshade.

To concentrate the solar light under some of the above mentioned fixtures we can provide a set of mirrors, for example one under the dangling parts to bounce the light passing by back up to the light fixture. We can provide another mirror under the top of the fixture to bounce the light back down. The top mirror will have a hole in it to allow the light source, the LED, to protrude through it. These mirrors can be slightly concave to help focus the light.

While most solar landscape lights have only one solar cell and one LED, we can provide fixtures having more than one solar cell and or more than one LED, thus creating a more powerful light, which in turn can illuminate larger and or more objects. These components may be incorporated into a single fixture, or in multiple fixtures within a single article of manufacture, such as by stacking them, spaced apart a distance, and having separate parts of the entire light assembly lit up by the different fixtures.

Fanatics, such as sports fanatics, often are willing to spend significant amounts of money to display their team spirit. This can drive the development and manufacturing of larger, more powerful, although more expensive solar light fixtures. This can also be true of patriotic fervor. Patriots are most likely willing to pay for bigger, brighter solar-lighted “windsocks” having patriotic themes, such as the US flag for example.

For examples of college and professional team windsocks see the following url:
http://www.universalshopping.com/flags.html

The variations on how the above-described solar light fixtures utilizing wind powered effects can be used is virtually unlimited. Ideally, the basic solar light fixture will be able to be used in a very wide array of effects with a wide array of purposes. This allows the manufacturer to combine the fixture with each of those effects, and sell larger volumes of the fixtures. Such volume sales help the manufacturer recuperate design, development, marketing, and associated costs quickly. It also allows the products to be introduced into a wider array of uses more quickly.

More powerful solar energy fixtures will allow other uses of these renewable energy devices to be developed. It is impossible to predict what they will eventually used with. The fixtures themselves can take on added circuitry to provide additional effects. Multi-colored lights can be switched on and off for example. Other electronic enhancements can be added as well. Sound effects can be introduced, along with a proximity or motion sensor, and having circuitry to generate sounds as a person approaches the fixture. Ghostly sounds for Halloween, a Christmas Carol, greetings effects, etc. All without use of hard wiring. The inducement to introduce such added effects can be greater sales of interesting solar powered products such as those outlined herein.

One aspect of the described inventions is we have brought solar landscape lights up from the ground level, or just above ground level, to eye level and above. There are solar “candles” that are meant to be positioned on tables, but these are not of the same order as the present inventions. The solar candles emit a steady-driven static light, whereas the present inventions are quite dynamic.

While we have focused on the use of LED's in our inventions we can also incorporate other light sources, such as solar powered fluorescent lights for example. These, as well as any other suitable light source can be utilized in the present inventions.

There are many variations of windsock, some having streamers of cloth to wave in a breeze, some have spinners that catch the wind and cause the windsock or portions of it to spin in the breeze. We can even cause different portions of the windsock to spin in opposite directions, and we can utilize multiple solar lights with these in a variety of combinations.

One nice aspect of the present inventions is they are suited to both high volume mass production for mass market distribution and sales, as well as to low volume, unique or one of a kind artistic production. We can fashion these to appeal to a very wide audience. Low cost units as well as higher value artistic pieces. The solar light fixtures can be of limited variations in design, while the accent items they are attached to can be unlimited in variation or design.

A solar light fixture for use with a windsock can substantially fill the mouth of a windsock, thus blocking wind from entering there. Or it can be substantially smaller than the mouth of the windsock, or have provisions for allowing air and wind to pass into the mouth of the windsock.

A windsock can be custom printed with a street number for example in order to display an address that may not normally be visible at night. Another option would be to put the name of the user on the windsock for prominent display. This can assist in finding a specific residence at night for example.

Windsocks may or may not have streamers attached to them.

There is a wide variety of landscape and architectural ornaments currently being produced that can benefit from being combined with a solar lighting fixture. Perhaps of primary interest of these are the ones designed to be suspended from above, and to move in the wind. These can be positioned under the solar light fixture and illuminated at night, thus extending the time they can be viewed and enjoyed.

### OBJECTS AND ADVANTAGES

Accordingly, the objects and advantages of the present invention include providing solar powered landscape and architectural light fixtures that
4. Combine the solar lights with windsocks, making the windsocks visible at night and producing additional pleasing effects.
5. Combine the solar lights with wind chimes, making the wind chimes and or the fixture visible at night and producing additional pleasing effects.
6. Combine solar lights with various landscape and architectural accent objects so they, and or the fixtures are visible at night to produce additional pleasing effects.
7. Combine solar landscape and architectural lighting with fabric and other shade materials to soften the effects of the light being produced, making them more inviting and or romantic.
8. Provide solar landscape and architectural lighting that the user is able to readily alter to better suit seasonal, holiday, and special occasion decor.

### SUMMARY OF THE INVENTION

In accordance with the present invention a solar powered landscape light & architectural accent device comprises a solar powered light fixture having one or more solar cells for converting sunlight into electrical energy and storing that energy in one or more batteries, along with the necessary associated circuitry to control charging of the batteries during the day and turning on the light source at night. It further comprises one or more of the following;
9. A windsock situated to be illuminated by the solar light fixture at night.
   4. Wind chimes situated to be illuminated by the solar light fixture at night.
      One or more wind catching spinners that cause one or more parts of the fixture assembly to rotate in a wind.
      One or more ornamental objects suspended below the light fixture, situated to be illuminated by the solar light fixture at night, and free to move in a breeze.
      One or more mirrors to reflect and focus light onto objects suspended below a solar powered light fixture and free to move in a breeze.
10. A cloth lampshade to subdue the light of the solar light fixture wherein the fixture, and or the lampshade is able to sway or otherwise move with some degree of freedom in a breeze.

### BRIEF DESCRIPTION OF THE DRAWINGS

FIG. 1 is a perspective view of the top of a suspended solar light fixture.

FIG. 2 is a perspective view of the bottom of a solar light fixture.

FIG. 3 is a perspective view of a wind catching spinner.

FIG. 4 is a perspective view of a detachable windsock fastening band.

FIG. 5 is a perspective view of a windsock

FIG. 6 is a perspective view of a combination solar light fixture and windsock.

FIG. 7 is a perspective view of a solar light fixture having provisions for allowing wind to pass through it, balancing pins, and an arc shaped hanger.

FIG. 8 is a perspective view of a tube shaped lampshade having integral elastic band.

FIG. 9 is a perspective view of a suspended solar light fixture in combination with a set of suspended ornamental objects and having a mirror suspended below to reflect light back up towards the suspended ornamental objects.

FIG. 10 is a perspective view of a set of ornamental objects suspended from a ring that is to be detachably connected to a solar light fixture.

FIG. 11 is a perspective view of wind chimes suspended from a ring that is to be detachably connected to a solar light fixture.

FIG. 12 is a perspective view of a combination solar powered lighting fixture and wind chime set.

### DETAILED DESCRIPTION OF THE PREFERRED EMBODIMENTS

A preferred embodiment of the present invention will be described more fully hereinafter. However, the invention should not be construed as being limited to the embodiments described herein. Rather, it is intended that the invention be construed broadly to encompass any and all embodiments of combined solar light fixtures and wind driven landscape and architectural accents and devices having the features or equivalents thereof, disclosed herein which are within the skill of an ordinary person in the relevant art. In the description, like reference numerals designate like or corresponding parts throughout the several figures. It is to be also understood that such terms as “inner”, “outer”, “upper” and “lower” are used in the description for purposes of locating one element relative to another and are not to be construed as limiting terms. Additionally, it should be understood that the illustrations provided in the figures are for the purpose of describing the invention, and are not intended to limit the scope of the invention in any manner. Also, various combinations of the elements of this invention can be used to create solar powered landscape and architectural accents and devices. It is to be understood that the exclusion of one or more elements is desirable when practical and the inclusion of one or more elements is desirable when the inclusion enhances the desired characteristics of the devices.

In the broadest sense, the solar powered landscape and architectural accents and devices of the present invention comprise a solar powered light fixture and a substantially wind driven landscape and or architectural accent and or device.

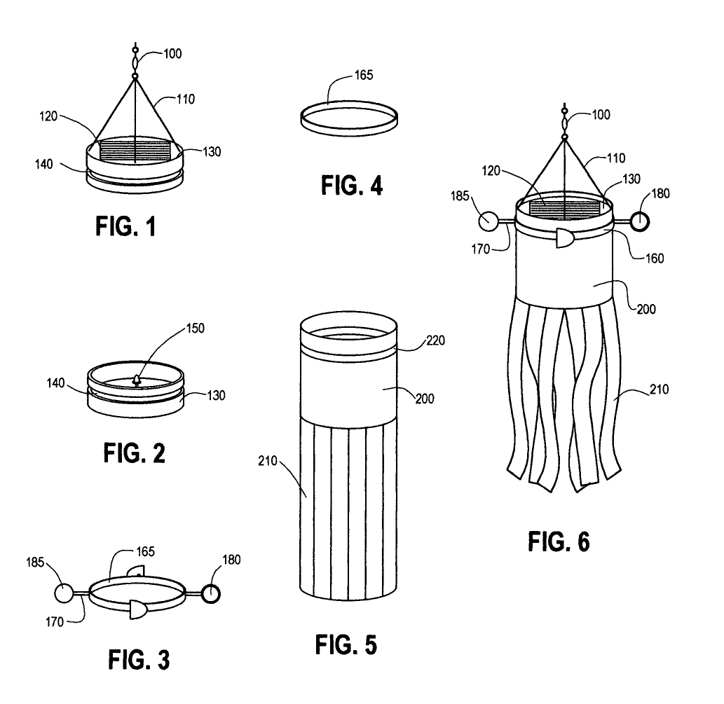

FIG. 1 shows a substantially cylindrically shaped solar light fixture 130, having a solar cell 120, a groove 140 for securing a windsock or lampshade thereto. The solar light fixture 130 being suspended from lines 110 comprised of string, fishing line, lightweight chain, etc, that are connected to spinner 100, commonly used with fishing lures, which allows the fixture to freely rotate. While fixture 130 is shown as cylindrical, it may comprise any suitable general shape, such as square, octagonal, etc.

FIG. 2 shows the bottom of solar light fixture 130, having lamp 150 located substantially in the center thereof. Not shown but located in the housing of solar light fixture 130 is the batteries and associated solar light fixture circuitry. Lamp 150 could comprise an LED, fluorescent bulb, or other suitable light source.

FIG. 3 shows a wind catching spinner having a ring shaped mount and or windsock or lampshade grip 165, with wind cups 175. Wind cup openings 180 are arranged and aligned to substantially catch a wind and wind cup backs 185 are designed to substantially pierce wind. The wind cups 175 are attached to ring shaped mount 165 via wind cup connectors 170. Wind cups 175 are shown as substantially bowl shaped but can be of any shape suitable for catching the wind and causing a fixture of the present invention to rotate in the wind. While three wind cups 175 are shown, any suitable number can be used. While the wind catching spinner is shown as a one-piece unit, the various parts can be discrete and assembled as needed to a fixture 130.

FIG. 4 shows a ring shaped windsock and or lampshade grip 165. Grip 165 can be as simple as a rubber band or any other suitable material for gripping a windsock 200 and holding it securely to a solar light fixture 130 around groove 140. In one preferred embodiment grip 165 is a substantially resilient ring of material that can be stretched or otherwise deformed into position, such as rubber. In another preferred embodiment ring 165 comprises a strip of material having hook and loop fasteners, such as Velcro, to detachably hold a windsock and or lampshade to fixture 130.

FIG. 5 shows a windsock having main body 200, streamers 210, and elastic band 220. The material of main body 200 and streamers 210 are of a suitable fabric such as rip stop nylon typically used in making kites. Alternately these parts can be made of a suitable plastic film such as polyester or other film or film combinations. Optimally, materials used to manufacture windsock FIG. 5 will be able to transmit a portion of the light emitted from solar light fixture 130 to enhance visibility of windsock FIG. 5. Elastic band 220 is stitched into the material of main body 200 and has sufficient strength to hold windsock FIG. 5 onto a solar light fixture FIG. 1 even in a strong wind, yet will be elastic enough to be easily removed by a user.

FIG. 6 shows an assembled combination solar light fixture 130, with a windsock having main body 200 and steamers 210 attached thereto and secured with wind catching spinner mount and windsock grip 165. Spinner cups 175 are arranged to catch a wind and cause the fixture to rotate, and showing streamers 210 moving in a breeze (not shown).

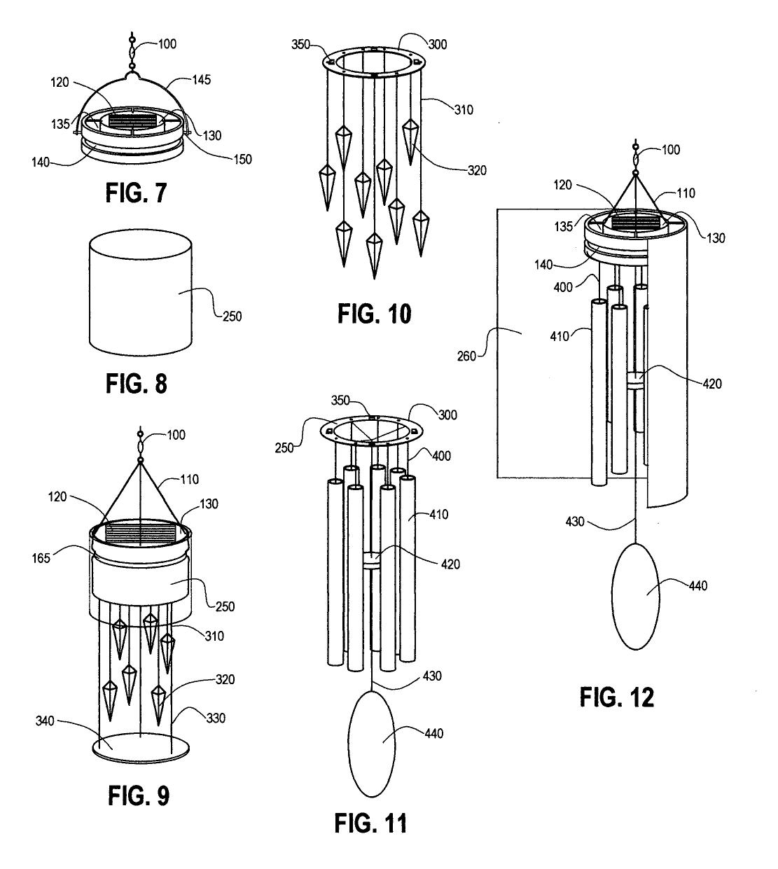

FIG. 7 shows a substantially cylindrically shaped solar light fixture 130, having passages 135 to allow air to pass through, arc shaped hanger 145, and balancing hanger pins 160. Balancing pins 160 may be integrally formed with fixture 130 or they may be detachably connected as with mating threaded members on pins 150 and fixture 130. Balancing pins 160 are situated on opposite sides of fixture 130 and substantially on or near a center of balance of fixture 130 such that a slight wind pushing on a windsock, (not shown), attached to fixture 130 would cause fixture 130 to tilt substantially into a the wind. Arc shaped hanger 145 may be plastic, metal or other suitable material to hold fixture 130 and any attached objects such as a windsock, and allow it to tilt on balancing pins 150. Small arc on top of arc shaped hanger 145 is located substantially in the center of arc 145 and serves to center a hanging device such as spinner 100 attached thereto.

FIG. 8 shows a tubular shaped lampshade 250. Lampshade 250 can comprise any suitable material such as fabrics, plastics and plastic films, or combinations thereof. While lampshade 250 is shown as tubular, other general shapes may be used, such as funnel or cone shapes. Also, while the surface of lampshade 250 is shown as smooth it can also be pleated or corrugated in form for example, to give other effects. Another option is to form lampshade 250 over a wire-form to provide specific or general shapes such as star shapes in the material. The top rim of lampshade 250 can be substantially different in shape from the bottom rim of lampshade 250. Additionally, fringe, short streamers, or other adornments may be incorporated into lampshade 250. Colorful printed materials for example may also be used. Additionally, a user could simply attach a silk scarf, (not shown), for example, to a solar light fixture FIG. 1 or FIG. 7, to substitute for lampshade FIG. 8 by wrapping it in a general tube shape around light fixture FIG. 1 or FIG. 7 and stretching band FIG. 4 over the scarf and holding it to the fixture FIG. 1 or FIG. 7.

FIG. 9 shows a combination solar light fixture 130 and a set of suspended ornamental objects 320 that are suspended by lines 310, and a mirror 340 suspended by lines 330. Additionally, a lampshade 250 is shown, attached to solar light fixture 130 and secured thereto by windsock and or lampshade grip 165. Ornamental objects 320 can be of any suitable size or shape and may be made of any suitable material to present an attractive display when moving in a breeze for example, or when idle. Additionally, another mirror, (not shown), may be positioned under solar light fixture 130 to further reflect light bouncing up to it from mirror 340, and return it downward to more effectively concentrate the light on the suspended objects 320.

FIG. 10 shows a set of suspended ornamental objects 320 suspended by lines 310 to suspension ring 300, having suspension ring to solar light fixture clips 350 to detachably connect suspension ring 300 to a solar light fixture. Suspension ring 300 may be comprised of plastic, metal, or any other suitable material for detachably connecting it to a solar light fixture 130 and to hold suspended objects 320 in position. While ornamental objects 320 are shown having regular facets, any suitable ornamental object may be used depending upon the effect desired.

FIG. 11 shows a set of wind chimes 410 suspended by wind chime suspension lines 400 to suspension ring 300, having clips 350 to detachably connect suspension ring 300 to a solar light fixture, wind catcher 440 connected to line 430 which is in turn connected to wind chime clapper 420, which is suspended via clapper suspension line 430 passing through it from wind catcher 440 to suspension ring 300. While wind chimes 410 are shown as tubular shaped, they may be of any suitable shape as can currently be found used in wind chimes. The material of wind chimes 410 may or may not be able to transmit light. Similarly, clapper 420 and wind catcher 440 may or may not be made using a material capable of transmitting light, such as translucent plastics, glass, crystal, etc. They too can be of any suitable shape to serve their respective purposes.

FIG. 12 shows a combination solar light fixture 130 and wind chimes 410, having flat cloth lampshade 260 partially wrapped around fixture 130 and wind chimes 410. Lampshade 260 extends below fixture 130 and blocks the viewer from seeing a harsh bare bulb or LED 150, and can serve to add illumination to an area when material of lampshade 260 is able to transmit some light. Additionally, when wind chimes 410 move in a breeze they can serve to cast shadows and or reflections and or refracted light onto the interior of lampshade 260 to provide a more interesting lighting fixture. While FIG. 12 shows a complete set of wind chimes able to sound a variety of tones, a single chime 410 can be used with a single solar light fixture 130 so that only a single tone is produced. In this instance a number of combination solar light fixture 130 and wind chime 410 can be brought together in a space to provide a complete set of wind chimes, with each individual fixture producing a single tone. One tone for one fixture, another tone for another fixture and so on.

Operation

Just as there are several preferred embodiments of solar powered landscape & architectural lighting and wind driven accents and devices, there are several preferred modes of operation.

Fundamentally the simplest mode of operation for each embodiment of these inventions is to position them in a location where they are able to receive sufficient solar light to operate the solar light fixture, and are able to move with a sufficient degree of freedom in a breeze. Normal care, cleaning and replacement of batteries in the solar light fixture 130 is also required.

For a combination solar light and windsock the most common mode of operation will be for a user to suspend the assembly from the eaves of a house, or on a flexible fiberglass rod, or a flagpole for example, in a location where it will be exposed to sufficient sunlight, and will also be free to blow in a breeze. The solar cell 120 of light fixture 130 faces upward to receive sunlight energy. Windsock 200 may be positioned around fixture 130 to substantially conceal fixture 130, or windsock 200 can be positioned somewhat lower on fixture 130 or even below fixture 130 to prominently show fixture 130. Top of windsock 200 cannot extend over solar cell 120 in such a way as to block sunlight from it. Normal care, cleaning and replacement of batteries in the solar light fixture 130 is also required.

For combination solar light and wind chimes FIG. 12, since wind chimes 410 are not expected to blow substantially off of a vertical orientation, the assembly doesn't need to be held very far away from otherwise obstructing objects, such as the side of a house, as is the case with the combination solar light and windsock FIG. 6. These can be kept closer to the side of a building for example. The primary requirements being the fixture receives sufficient sunshine to operate properly, and they are exposed to enough wind to satisfactorily affect the chimes 410. Normal care, cleaning and replacement of batteries is also required.

Similarly, with combination solar light 130 and suspended accent objects, FIG. 9, FIG. 10, where the accent objects 320 are not overly long or expected to blow substantially off of a general vertical orientation, they too can be mounted closer to the side of buildings or other objects. Again, the fixture 130 needs to receive sufficient sunshine, and preferentially, some amount of breeze or wind in order to cause the objects 320 to move in the wind, but this action is not absolutely necessary.

Combination windsock and solar light fixtures FIG. 6 have the added function, or mode of operation wherein the user detaches the windsock FIG. 5, and attaches a different windsock FIG. 5 to decorate a space with the changing seasons, holidays and other special occasions. When grip 165 comprises a simple rubber band to hold the windsock FIG. 5 onto the solar light fixture 130, the user pulls the rubber band 165 off, slips off the windsock FIG. 5, slips on a new windsock FIG. 5, then repositions the rubber band 165 to hold the windsock FIG. 5 on the light fixture 130. A similar sequence is used when the rubber band 165 is substituted with a tie string, or a clip, buttons, hooks and eyes, or other fastening method is used, with the necessary steps of unfastening and refastening those devices as required. When elastic band 165 is stitched into main body 200 of windsock FIG. 5, the user stretches the windsock on and off the solar light fixture FIG. 1, allowing elastic band 165 to grip fixture FIG. 1 around groove 140.

An optional mode of operation is to mount onto the combined solar fixture and landscape and or architectural accent, a wind catching spinner FIG. 3, designed to catch the wind and cause the solar light fixture 130, and or combining features, to rotate or spin in the wind. The wind catching spinner FIG. 3 may be stretched over, snapped on, tied, clipped on, or otherwise fastened to the assembly. Alternately, spinner FIG. 3 may be integrally formed with solar light fixture 130, (not shown).

An additional mode of operation is to mount the solar fixture 130 on a rigid stand for example, (not shown), or to suspend it, and put a cloth lampshade FIG. 8, over the fixture 130 to subdue the light and to expose the cloth shade FIG. 3 to any breeze. Additionally, cloth lampshades FIG. 3 can be changed out to reflect themes of seasons, holidays, and other special occasions. While FIG. 3 shows a tubular shaped lampshade, this can be formed in any suitable shape. The surface of lampshade FIG. 3 may be pleated, corrugated, square, octagonal, etc. Wires and or other rigid member, also not shown, can be used to assist in forming suitable shapes of lampshades FIG. 3. Additionally, lampshade FIG. 3 may comprise a substantially flat piece of cloth 260, as shown in FIG. 12 that is wrapped around fixture 130 and secured accordingly.

An additional mode of operation is to combine features of the present inventions to create additional effects. For example a solar light fixture FIG. 1 or FIG. 7 can be joined with suspended ornamental objects FIG. 10 and a lampshade FIG. 8. As a wind blows the fixture FIG. 1 or FIG. 7 causing it to sway, and or causes suspended ornamental objects FIG. 10 to sway or otherwise move, light and or shadows will be cast onto lampshade FIG. 8 creating interesting patterns of light and dark. This can similarly be done with adding a lampshade to a wind chime or set of wind chimes FIG. 12. In these modes it is best to have a portion of the suspended objects and or the wind chimes hanging below the bottom of lampshade FIG. 8 so a wind can cause it to move. Additionally, it is best when lampshade FIG. 8 is substantially sheer and or quite able to transmit subtle light effects such as dim reflections and shadows.

### CONCLUSION, RAMIFICATIONS, AND SCOPE

Thus the reader will see that the solar powered landscape and architectural accents and devices of the present invention provide substantially improved solar powered light fixtures and accent devices having unique characteristics, providing attractive lighting, along with wind driven effects and devices such as wind chimes, windsocks, etc. The wide array of potential combinations include festive, seasonal, holiday and special occasion themes, and the ability to change these accordingly. Additionally, the present invention provides the utility of allowing a user to witness the relative strength and direction of a wind from a distance, such as from inside their home.

These inventions also bring solar powered landscape and architectural lighting fixtures up from a typical ground level orientation to more of an eye-level and above eye-level orientation such that the light given by these devices can be more thoroughly enjoyed.

The present inventions also serve to expand the uses of free energy devices such as those driven by solar and wind power. Using free energy, or renewable energy, being of greater and greater importance as the energy reserves on Earth are depleted. Employing free energy devices of this nature serves to increase manufacturing, development and marketing of such devices, which in turn leads to ever increasing efficiencies of them.

It is to be understood that the forgoing description and specific embodiments shown and described herein are merely illustrative of the best modes of the invention and the principals thereof, and that various modifications and additions may be made by those normally skilled in the art without departing unnecessarily form the spirit and scope of the invention, which is intended to be limited only by the scope of the following claims. Accordingly, the present invention is intended to be construed broadly enough to encompass any and all embodiments and equivalents thereof within the spirit and scope of the appended claims.

1. In combination: a solar powered light and a substantially decorative windsock whereby said solar powered light illuminates said windsock at night, allowing extended and unique viewing of said windsock and providing an indicator of relative wind speed and direction at night.

2. In combination: the solar light and windsock of claim 1 wherein said combination is tethered to a substantially flexible support whereby said combination solar light and windsock is substantially free to move dynamically in a wind with the additional dynamic movement induced by the flexing of said flexible support.

3. In combination: a solar powered light and one or more wind chimes.

4. In combination: a solar powered light and one or more substantially wind driven art objects comprising wind chimes, decorative lampshades, wind catching spinners, streamers, and suspended art objects.
